(19) United States
(12) Patent Application Publication
(10) Pub. No.: US 2006/0205215 A1
(43) Pub. Date: Sep. 14, 2006

(54) Semiconductor device and method for manufacturing the same

(76) Inventor: Kouji Matsuo, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/366,541

(22) Filed: Mar. 3, 2006

(30) Foreign Application Priority Data
Mar. 4, 2005 (JP) 2005-060947

(51) Int. Cl. H01L 21/44

(52) U.S. Cl. 438/685

(57) ABSTRACT

The semiconductor device is manufactured forming by polysilicon film on a gate insulating film formed on a semiconductor substrate; introducing a first metal into a portion of a region of the polysilicon film; forming a pre-gate electrode from the polysilicon film, the polysilicon film having the first metal introduced; and transforming the pre-gate electrode into a silicide in its entirety to form a suicide film and to form a metal layer by causing the first metal to be precipitated between the gate insulating film and the silicide film. Thereby, a gate electrode in a particular MOSFET has a first metal layer being the undermost layer and a silicide layer over the first metal layer.

### CROSS REFERENCE TO RELATED APPLICATIONS

This application is based upon and claims the benefit of priority from the prior Japanese Patent Application No. 2005-60947, filed on Mar. 4, 2005, the entire contents of which are incorporated herein by reference.

### BACKGROUND OF THE INVENTION

1. Field of the Invention

The present invention relates to a semiconductor device and a method for manufacturing the same.

2. Background Art

Conventionally, polysilicon is mainly used for gate electrodes in a MOSFET. The reasons include a stable interface between a gate electrode made of polysilicon and an underlying gate oxide layer, and good adhesion of a gate electrode made of polysilicon to an underlying gate oxide layer. In the MOSFET, the work function of a gate electrode in an n-type MOSFET is defined to approximately 4.1 eV and that of a gate electrode in a p-type MOSFET is defined to approximately 5.2 eV by changing impurity elements, which are ion-implanted into polysilicon films, for each n-type and p-type MOSFET. In this way, low threshold voltage and/or low switching voltage has been achieved by decreasing the work function of the gate electrode in the n-type MOSFET and increasing the work function of the gate electrode in the p-type MOSFET.

However, with increasing miniaturization, a problem of depletion in gates is increasingly indispensable with conventional MOSFETs which use polysilicon for their gate electrodes. The depletion has made it difficult to lower switching voltage. The depletion in the gates is caused due to the fact that the polysilicon film constituting the gate electrodes is semiconductor. Because the concentration of donors and acceptors in the polysilicon film has an upper limitation, the depletion cannot be eliminated with gates made of polysilicon. Therefore, use of metal gate electrodes has been proposed to eliminate the depletion and achieve low switching voltage even in a miniaturized MOSFET.

However, the metal gate electrodes proposed heretofore suffer from many problems. For example, a CMOS transistor using a metal gate electrode suffers from problems of low reliability and a difficulty of incorporation into mass production. Therefore, metal gate electrodes have not been put into practical use and polysilicon electrodes is still used for the gate electrodes of CMOS transistors.

### SUMMARY OF THE INVENTION

According to an aspect of embodiments according to the invention, there is provided a semiconductor device having a plurality of MOSFETs formed on a semiconductor substrate, a gate electrode in at least one particular MOSFET of the MOSFETs including: a first metal layer being the undermost layer; and a silicide layer over the first metal layer.

According to a further aspect of embodiments according to the invention, there is provided a method for manufacturing a semiconductor device, including: forming polysilicon film on a gate insulating film formed on a semiconductor substrate; introducing a first metal into a portion of a region of the polysilicon film; forming a pre-gate electrode from the polysilicon film, the polysilicon film having the first metal introduced; and transforming the pre-gate electrode into a silicide in its entirety to form a silicide film and to form a metal layer by causing the first metal to be precipitated between the gate insulating film and the silicide film.

According to a still further aspect of embodiments according to the invention, there is provided a method for manufacturing a semiconductor device having a plurality of MOSFETs, a gate electrode in at least one particular MOSFET of the MOSFETs is formed by: forming polysilicon film on a gate insulating film formed on a semiconductor substrate; introducing a first metal into a portion of a region of the polysilicon film; forming a pre-gate electrode from the polysilicon film, the polysilicon film having the first metal introduced; and transforming the pre-gate electrode into a silicide in its entirety to form a silicide film and to form a metal layer by causing the first metal to be precipitated between the gate insulating film and the silicide film.

### BRIEF DESCRIPTION OF THE DRAWINGS

FIG. 1 is a sectional view of CMOS transistors of the first embodiment according to the present invention;

FIG. 2 is a sectional view illustrating a method of manufacturing the CMOS transistors of the first embodiment according to the present invention;

FIG. 3 is a sectional view illustrating a method of manufacturing the CMOS transistors of the first embodiment according to the present invention, subsequent to FIG. 2;

FIG. 4 is a sectional view illustrating a method of manufacturing the CMOS transistors of the first embodiment according to the present invention, subsequent to FIG. 3;

FIG. 5 is a sectional view illustrating a method of manufacturing the CMOS transistors of the first embodiment according to the present invention, subsequent to FIG. 4;

FIG. 6 is a sectional view illustrating a method of manufacturing the CMOS transistors of the first embodiment according to the present invention, subsequent to FIG. 5;

FIG. 7 is a sectional view illustrating a method of manufacturing the CMOS transistors of the first embodiment according to the present invention, subsequent to FIG. 6;

FIG. 8 is a sectional view illustrating a method of manufacturing the CMOS transistors of the first embodiment according to the present invention, subsequent to FIG. 7;

FIG. 9 is an experimental data by which the work function of thin antimony (Sb) formed on a gate oxide is determined, conducted by the inventor;

FIG. 10 is a sectional view of CMOS transistors of the second embodiment according to the present invention;

FIG. 11 is a sectional view illustrating a method of manufacturing the CMOS transistors of the second embodiment according to the present invention;

FIG. 12 is a sectional view illustrating a method of manufacturing the CMOS transistors of the second embodiment according to the present invention, subsequent to FIG. 11;

FIG. 13 is a sectional view illustrating a method of manufacturing the CMOS transistors of the second embodiment according to the present invention, subsequent to FIG. 12;

FIG. 14 is a sectional view illustrating a method of manufacturing the CMOS transistors of the second embodiment according to the present invention, subsequent to FIG. 13;

FIG. 15 is a sectional view illustrating a method of manufacturing the CMOS transistors of the second embodiment according to the present invention, subsequent to FIG. 14;

FIG. 16 is a sectional view of CMOS transistors using metal gate electrodes according to implementation of the inventor;

FIG. 17 is a sectional view illustrating a method of manufacturing the CMOS transistors using the metal gate electrodes;

FIG. 18 is a sectional view illustrating a method of manufacturing the CMOS transistors using the metal gate electrodes, subsequent to FIG. 17;

FIG. 19 is a sectional view illustrating a method of manufacturing the CMOS transistors using the metal gate electrodes, subsequent to FIG. 18;

FIG. 20 is a sectional view illustrating a method of manufacturing the CMOS transistors using the metal gate electrodes, subsequent to FIG. 19;

FIG. 21 is a sectional view illustrating a method of manufacturing the CMOS transistors using the metal gate electrodes, subsequent to FIG. 20;

FIG. 22 is a sectional view of a variation of CMOS transistors of the first embodiment according to the present invention; and

FIG. 23 is a sectional view of a variation of CMOS transistors of the second embodiment according to the present invention.

### DESCRIPTION OF THE EMBODIMENTS

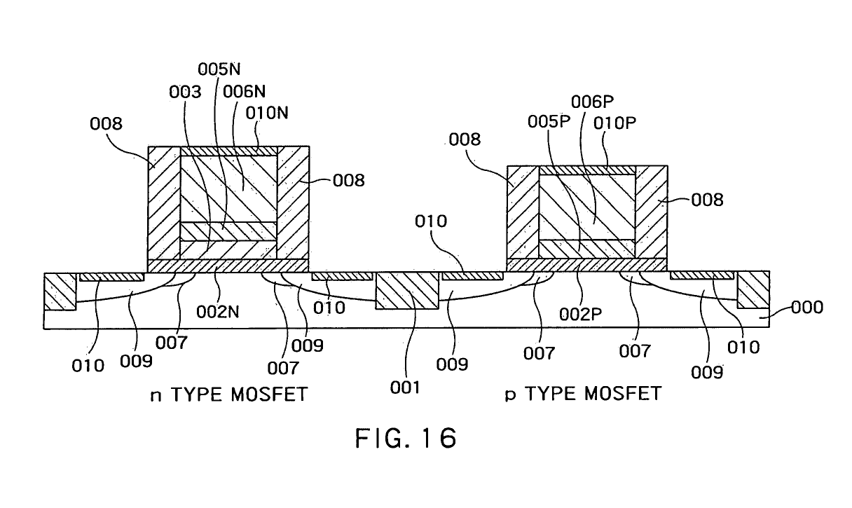

FIG. 16 shows an example of CMOS transistors using metal gate electrodes according to implementation of the inventor. An isolation region 001 is formed on a silicon substrate 000. An n-type MOSFET is formed on the left side of the isolation region 001 in the center of the drawing, and p-type MOSFET on the right side. In the p-type MOSFET on the right side of the drawing, shallow junction regions 007, deep junction regions 009, and cobalt suicides 010 are formed in portions of the silicon substrate 000. A p-side gate insulating film 002P made of silicon oxynitride of approximately 1 nm thick is formed on the substrate 000. A tungsten nitride film (p-side gate electrode) 005P of approximately 10 nm thick, a polysilicon film 006P, and a cobalt silicide 010P are sequentially formed on the p-side gate insulating film 002P. The sides of these gate electrode sections are covered by gate sidewalls 008. Similarly, in the n-type MOSFET on the left side of the drawing, shallow junction regions 007, deep junction regions 009, and cobalt suicides 010 are formed in portions of the silicon substrate 000. A n-side gate insulating film 002N made of silicon oxynitride of approximately 1 nm thick is formed on the substrate 000. A titanium nitride film (n-side gate electrode) 003 of approximately 10 nm thick, a tungsten nitride film 005N of approximately 10 nm thick, a polysilicon film 006N, and a cobalt silicide 010N are sequentially formed on the n-side gate insulating film 002N. The sides of these gate electrode sections are covered by gate sidewalls 008.

A method for manufacturing the CMOS transistors in FIG. 16 will be described below.

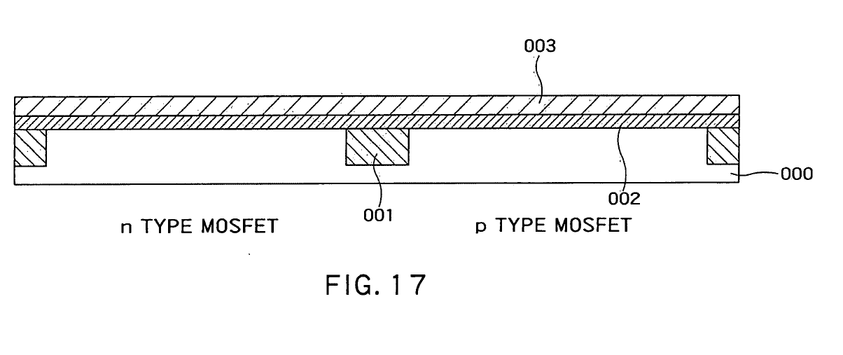

As shown in FIG. 17, the isolation region 001 is first formed on the silicon substrate 000 using a technique such as STI. Then, a gate insulating film 002 made of silicon oxynitride of approximately 1 nm thick and a titanium nitride film 003 of approximately 10 nm thick are formed.

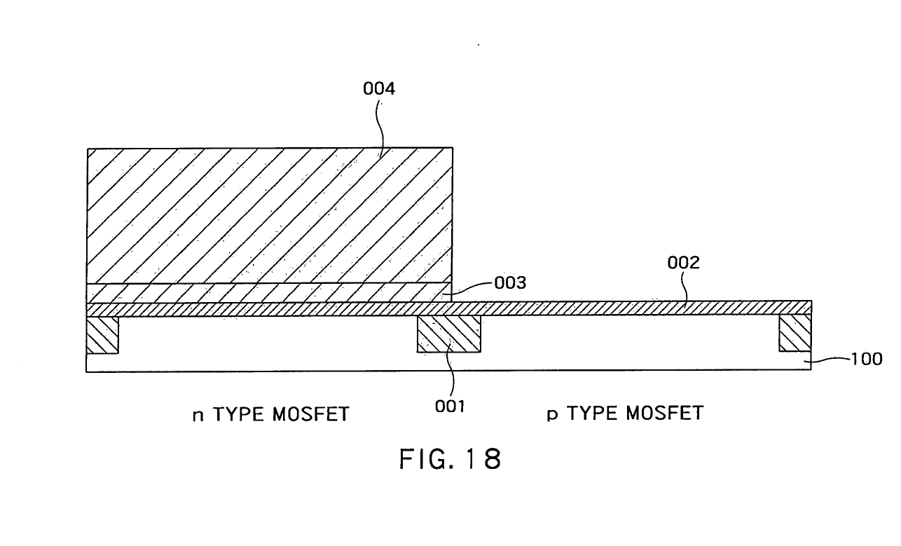

Then, photoresist 004 is formed on the titanium nitride film 003 in FIG. 17. Thereafter, as shown in FIG. 18, lithography techniques are used to create an opening in the photoresist 004 only in a region for forming p-type MOSFETs, and the portion of titanium nitride film 003 formed in the region for forming p-type MOSFETs is wet-etched away using hydrogen peroxide solution.

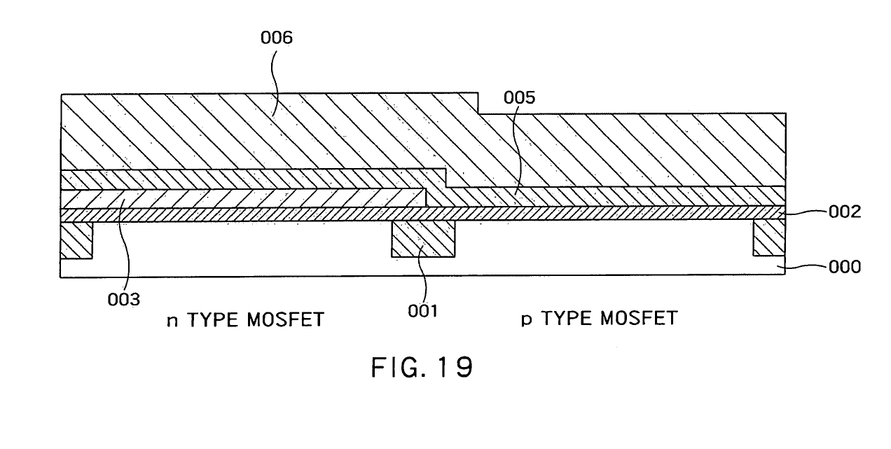

Then, after the photoresist 004 is removed, a tungsten nitride film 005 of approximately 10 nm thick and a polysilicon film 006 are sequentially formed as shown in FIG. 19. If the polysilicon film 006 has already contained phosphor and the like, a step of injecting impurities using ion implantation techniques is omitted. Thereafter, the substrate is heated on the order of 800° C. to activate impurities in the polysilicon film 006.

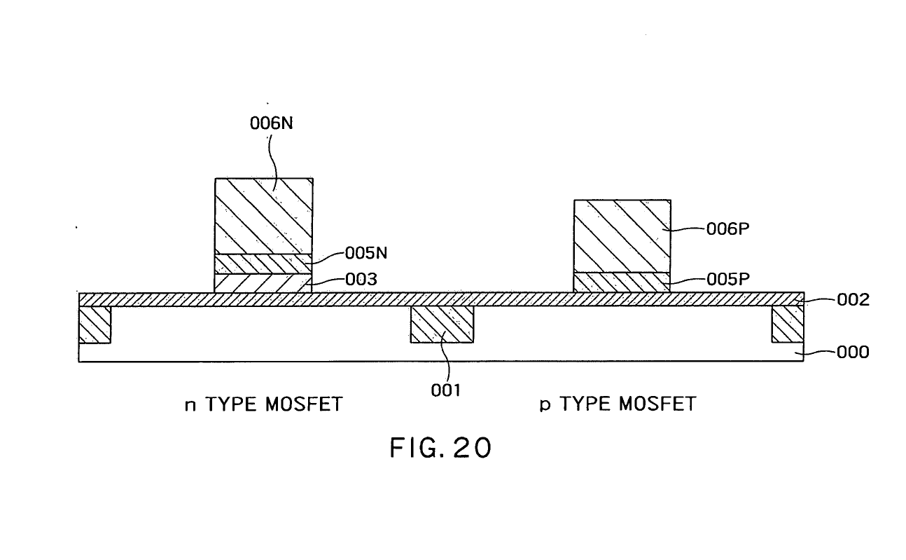

Then, as shown in FIG. 20, lithography and etching techniques are used to shape the polysilicon film 006, tungsten nitride film 005 and titanium nitride film 003, forming n-side gate electrode sections 003, 005N and 006N as well as p-side gate electrode sections 005P and 006P.

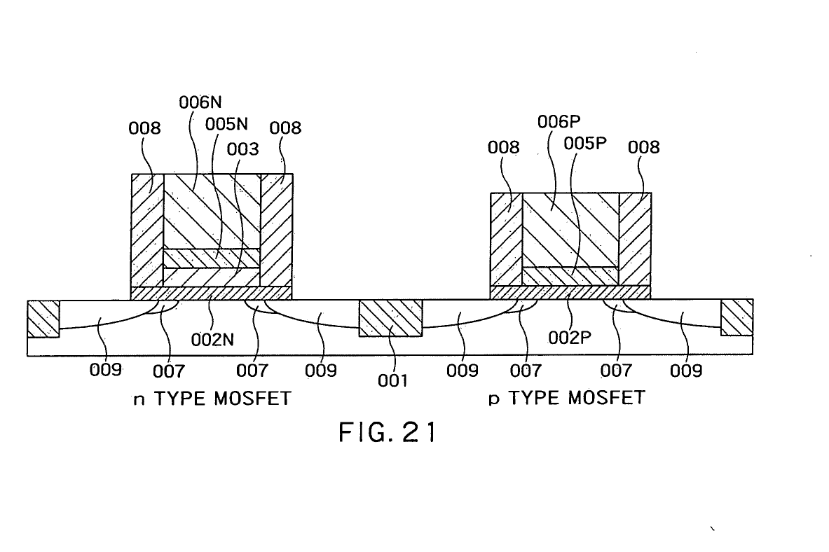

Then, as can be seen in FIG. 21, shallow junction regions 007 for sources and drains are formed by ion-implanting impurities into them using gate electrode sections as masks, and activating them. Then, as shown in FIG. 17, gate sidewalls 008 made of silicon nitride are formed, while the portions of the gate insulating film 002 on the sources and drains are etched away. Thereafter, ion implantation and activation are performed to form deep junction regions 009 for the sources and drains.

Then, cobalt silicides 010 are formed through salicide techniques on sources and drains as well as on gates. In this way, the CMOS in FIG. 16 is completed.

In thus formed CMOS, titanium nitride film having a smaller work function is used for gate electrodes in the n-type MOSFET and tungsten nitride film having a larger work function for gate electrodes in the p-type MOSFET to achieve low switching voltage.

However, the CMOS in FIG. 16 does not necessarily facilitate mass production. Specifically, in the CMOS in FIG. 16, the n-type MOSFET and the p-type MOSFET have different gate electrode sections of different structure, because the gate electrode section of the n-type MOSFET has the titanium nitride film 003, while the gate electrode section of the p-type MOSFET does not have one. To fabricate this structure, the titanium nitride film 003 deposited in the p-type MOSFET region is removed through wet etching as shown in FIG. 18. However, because the gate insulating film 002 in the p-type MOSFET region is exposed to wet-etching solution during the removal, pinholes caused by etching may be generated in the gate insulating film 002 on the right side of the drawing. These pinholes may cause a problem of significant degradation of reliability of the gate insulating film 002. In addition, because the structure of the gate electrode sections is different between the n-type MOSFET and the p-type MOSFET, it is difficult to shape both gate electrode sections at the same time, as can be seen in FIG. 19. Furthermore, as can be seen in FIG. 20, it is also difficult to perform etching with high selection ratio between the titanium nitride film 003/tungsten nitride film 005P and the gate insulating film 002. In addition, when sputtering is used to deposit the tungsten nitride film 005 and/or the titanium nitride film 003, atoms of tungsten and/or titanium are likely to be injected into the gate insulating film 002, causing a problem of degradation of reliability of the gate insulating film 002. Even when CVD is used for film deposition to avoid the problem, impurities contained in the deposition gas are captured into the tungsten nitride film 005 and/or the titanium nitride film 003, resulting in significant degradation of reliability of the gate insulating film 002.

The present invention has been made by the inventor in order to solve disadvantages of the above devices.

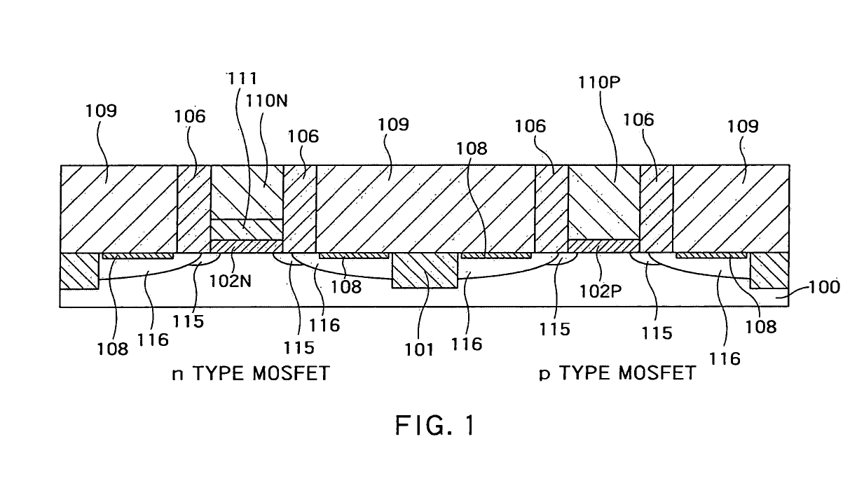

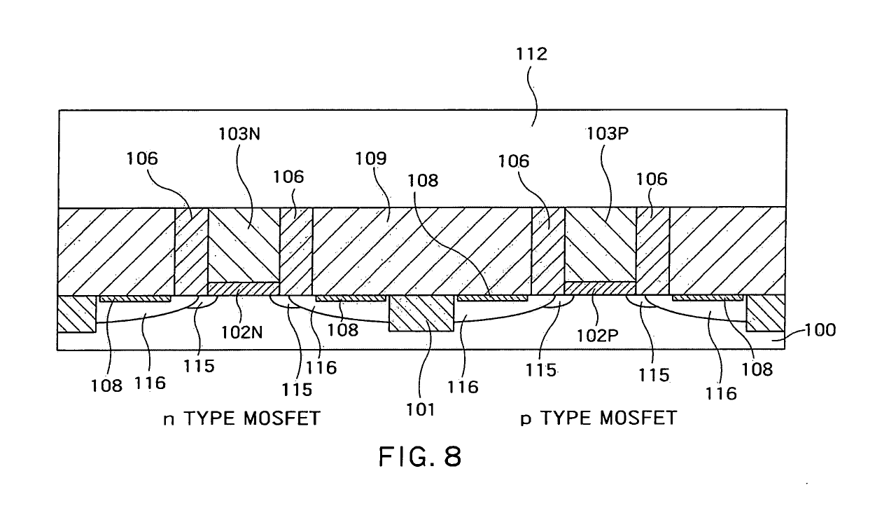

Embodiments of CMOS (semiconductor devices) according to the invention will now be described with reference to drawings. One of the features of the CMOS according to the embodiments is that, as shown in FIG. 1 for example, the structure has a thin (1 nm or less), n-side gate electrode (first gate electrode) 111 made of antimony formed on an n-side gate insulating film (second gate insulating film) 102N, and an n-side gate wiring layer 110N made of antimony-added platinum silicide, in a gate electrode section of an n-type MOSFET. The n-side gate electrode 111 made of antimony can be obtained by; as can be seen in FIG. 8, adding antimony to a polysilicon film 103N in an n-type MOSFET region; forming a platinum film 112 on the polysilicon film 103N; and using salicide techniques to transform the polysilicon film 103N into a platinum silicide film while causing antimony atoms to be precipitated (snow plowing effect). The CMOS achieves low threshold and/or switching voltage because of antimony having a smaller work function used for the n-side gate electrode 111 and PtSi having a larger work function for the p-side gate electrode 110P. In addition, because the n-side and p-side gate electrode sections can be formed at the same time according to the manufacturing method (see FIG. 8), high reliability is provided and mass production is facilitated. Two embodiments will be described below.

### First Embodiment

FIG. 1 is a sectional view of CMOS transistors of the first embodiment according to the present invention. An isolation region 101 is formed on a silicon substrate 100. An n-type MOSFET is formed on the left side of the isolation region 101, and p-type MOSFET on the right side. In the p-type MOSFET on the right side of the drawing, shallow junction regions 115, deep junction regions 116, and nickel silicides 108 are formed in portions of the silicon substrate 100. A p-side gate insulating film 102P made of silicon oxynitride of approximately 1 nm thick is formed on the substrate 100. A platinum silicide (PtSi) film 110P of approximately 50 nm thick is formed on the p-side gate insulating film 102P. The platinum silicide film 110P is used for a p-side gate electrode. The term “p-side gate electrode section” is used herein to represent a combination of the p-side gate electrode 110P and p-side gate insulating film 102P. The sides of the p-side gate electrode section are covered by gate sidewalls 106. Similarly, in the n-type MOSFET on the left side of the drawing, shallow junction regions 115, deep junction regions 116, and nickel silicides 108 are formed in portions of the silicon substrate 100. A n-side gate insulating film 102N made of silicon oxynitride of approximately 1 nm thick is formed on the substrate 100. A thin (1 nm or less), antimony precipitated layer 111 is formed on the n-side gate insulating film 102N. The antimony precipitated layer 111 is used for an n-side gate electrode. A platinum silicide (PtSi) film 110N is formed on the n-side gate electrode 111, and the platinum silicide film 110N is used for an n-side gate wiring layer. The term “n-side gate electrode section” is used herein to represent a combination of the n-side gate wiring layer 111, n-side gate electrode 110N, and n-side gate insulating film 102N. The sides of the n-side gate electrode section are covered by gate sidewalls 106.

In the CMOS in FIG. 1, the n-side gate electrode 111 is made of a metal, antimony, and the p-side gate electrode 110P is made of another metal, PtSi, and providing a structure having dual metal electrodes.

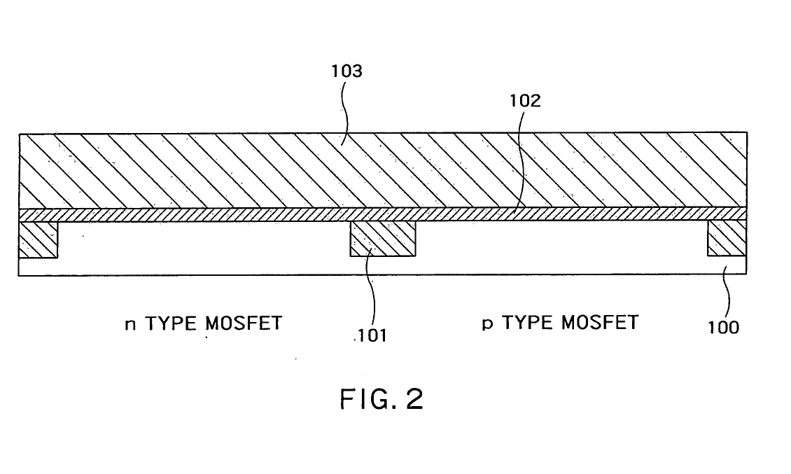

A method for manufacturing the MOSFET in FIG. 1 will now be described with reference to FIGS. 2 to 8.

(1) As shown in FIG. 2, the isolation region 101 is first formed on the silicon substrate 100 using a technique such as STI. Then, the gate insulating film 102 made of silicon oxynitride on the order of 1 nm is deposited and a polysilicon film 103 on the order of 50 nm is deposited. In the drawing, a region for forming n-type MOSFETs is to the left, and a region for forming p-type MOSFETs is to the right.

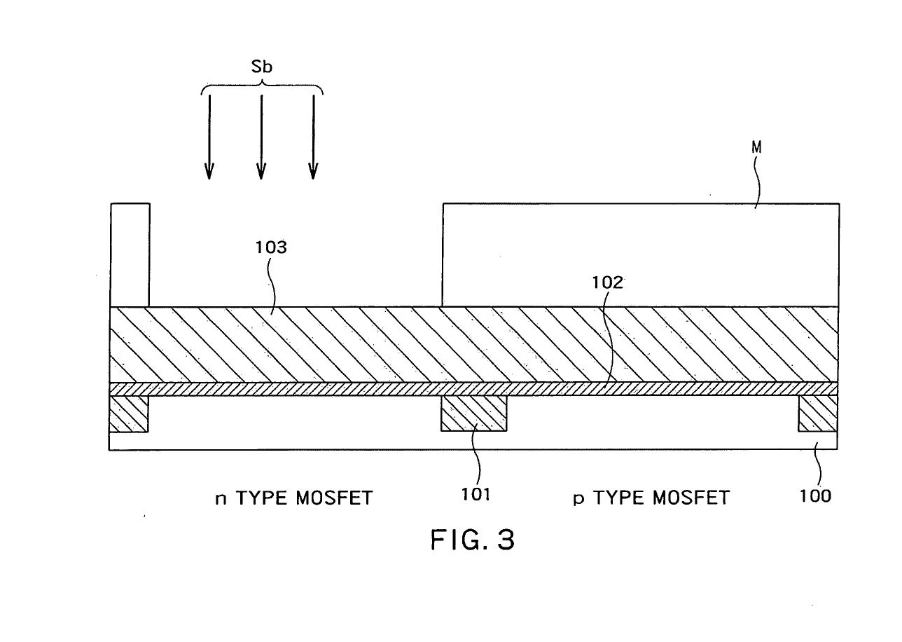

(2) Then, as shown in FIG. 3, a mask M is formed on the polysilicon film 103, and lithography and ion-implantation techniques are used to inject antimony into the polysilicon film 103 in the n-type MOSFET region on the left side of the drawing. The ion implantation dose of antimony at this time is on the order of 1E16/cm².

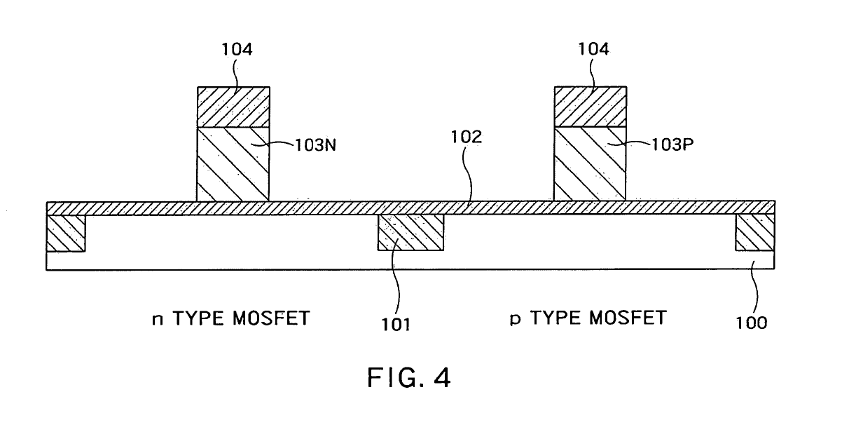

(3) Then, after the mask M in FIG. 3 is removed, a cap film 104, which consists of silicon nitride and has thickness on the order of 20 nm, is deposited on the polysilicon film 103, as can be seen in FIG. 4. Thereafter, as shown in FIG. 4, lithography and etching techniques are used to shape the cap film 104 and polysilicon film 103 into gates, and thus a polysilicon film 104P on the p-side and a polysilicon film 104N on the n-side are formed.

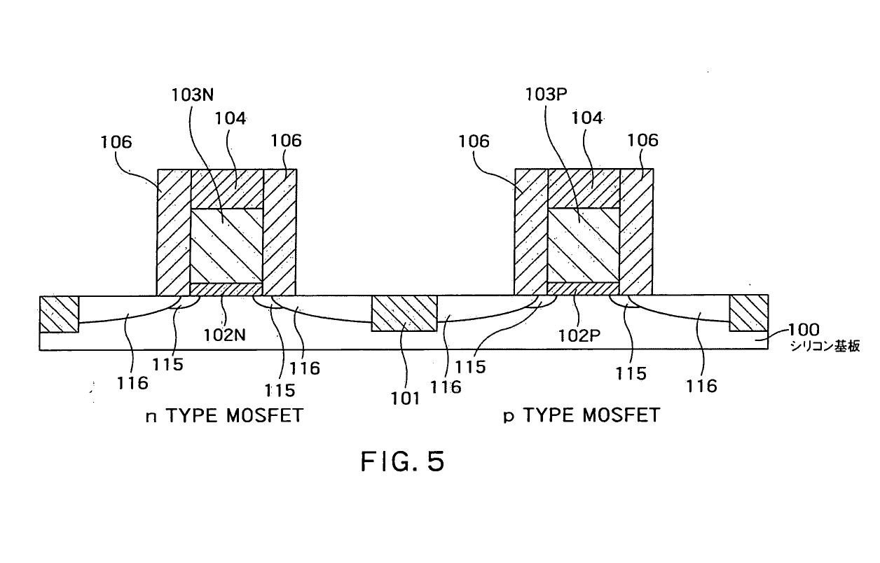

(4) Then, as can be seen in FIG. 5, portions of the gate insulating film 102 (on the surfaces of source and drain regions) other than those in p-side and n-side gate electrode sections are wet-etched away to form the p-side gate insulating film 102P and n-side gate insulating film 102N. Then, impurities are ion-implanted using the gate electrode sections as masks, and shallow junction regions 115 for sources and drains are formed through thermal processes. Then, the gate sidewalls 106 on the order of 30 nm, which are made of, for example, silicon nitride, are formed as shown in FIG. 5. Thereafter, the gate sidewalls 106 and gate electrode sections are used as a mask for ion-implantation to form deep junction regions 116 for sources and drains.

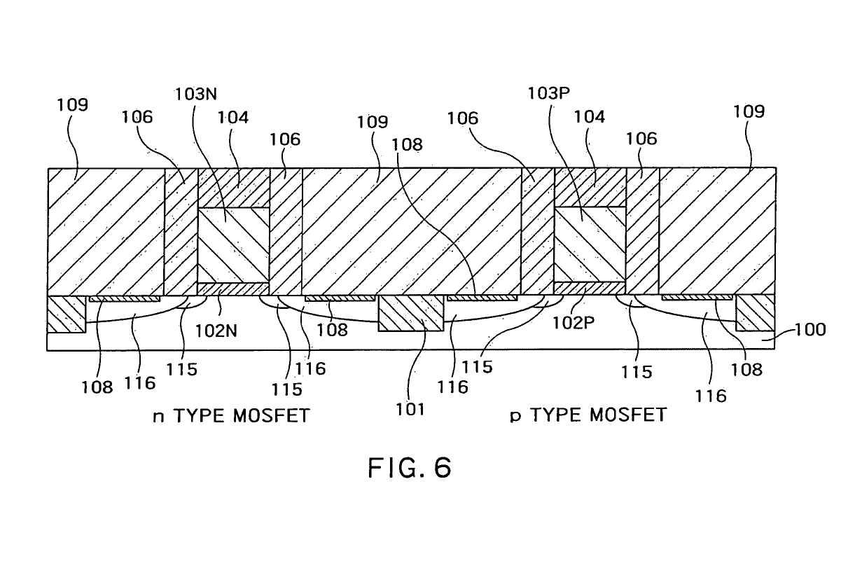

(5) Then, as shown in FIG. 6, nickel suicides 108 are selectively formed through salicide techniques on source and drain surfaces exposing Si. Then, an interlayer film 109 is deposited and planarized by such as CMP to expose top surfaces of the cap film 104 and gate sidewalls 106.

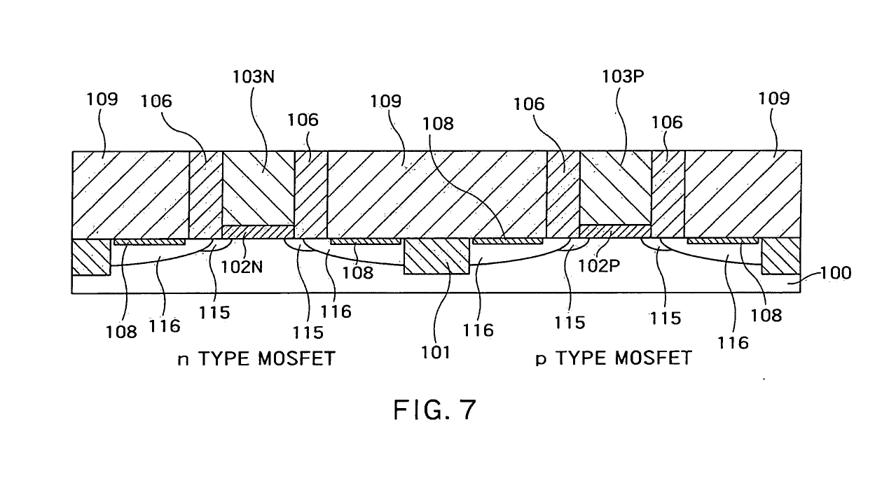

(6) Then, as shown in FIG. 7, the gate sidewalls 106 and cap films 104 are etched using such as RIE to expose top surfaces of the polysilicon films 103.

(7) Then, as shown in FIG. 8, a Pt film 112 of approximately 80 nm thick is formed by sputtering. Thereafter, salicide techniques are used to transform the polysilicon films 103N and 103P into PtSi films 110N and 110P, unreacted portions of the Pt film removed by such as royal water, and thus the CMOS in FIG. 1 is completed. In the above salicide techniques, thickness of the Pt film and a thermal process for salicide are adjusted to transform all the polysilicon films 103N and 103P into PtSi. Specifically, a thermal process on the order of 400° C. is used to transform all the polysilicon films 103N and 103P into PtSi films 110N and 110P. During the salicide reaction, the phenomenon, that some antimony atoms contained in the polysilicon (Sb) film 103 in the n-type MOSFET region may be ejected from thus formed PtSi films, is occurred (snow plowing effect). As a result, antimony is driven and precipitated onto an interface between the gate insulating film 102N and PtSi film 110N, and/or an interface between the gate sidewalls 106 and PtSi film 110N. At least on the order of few layers of atoms, or approximately 1 nm or less in thickness, of antimony precipitated layer 111 is formed between the n-side gate insulating film 102N and n-side PtSi (Sb) film 110N. After the antimony precipitated layer 111 is formed, antimony still remains in the n-side PtSi (Sb) film 110N, and is distributed so that the concentration is increased as the bottom of the drawing reaches closer. Thus formed antimony precipitated layer 111 will be the n-side gate electrode. In this way, the CMOS in FIG. 1 having the n-side gate electrode (n-side metal gate electrode) of antimony precipitated layer 111 is completed.

Although the CMOS in FIG. 1 formed by a manufacturing method described above uses metal gate electrodes, it suffers less degradation of reliability and/or mass productivity over conventional CMOS transistors which use polysilicon for their gate electrodes.

Specifically, because the CMOS in FIG. 1 can be fabricated without a process for creating the antimony precipitated layer 111, substantially no pinhole may be generated in the insulating films 102N and 102P (see FIG. 4). Therefore, the reliability will not be degraded.

In addition, as can be seen in FIG. 4, the p-side gate electrode section and the n-side gate electrode section have the same main components in the CMOS in FIG. 1, and therefore, both electrode sections can be processed at the same time. During the processes, the polysilicon film 103 can be processed using established techniques similar to conventional processes. In the CMOS in FIG. 1, because the n-side metal gate electrode 111 is formed through precipitation, deposition and/or processing of the metal gate electrode 111 are not required. These also contribute to avoiding degradation of the mass productivity.

On the contrary, proposed metal gate electrodes require, for example, deposition and/or processing of a tungsten nitride film 005 and/or titanium nitride film 003, as shown in FIGS. 5 and 6. These cause degradation of the reliability and/or mass productivity.

In addition, the CMOS in FIG. 1 may achieve lower switching voltage than the CMOS transistors which use polysilicon.

Specifically, the CMOS in FIG. 1 has dual metal gate electrodes in which the n-side gate electrode 111 is the antimony precipitated layer and the p-side gate electrode 110P is the PtSi film. These metal gate electrodes may eliminate depletion and achieve low switching voltage. Additionally, in the CMOS in FIG. 1, the work function of PtSi which makes up the p-side gate electrode 110P is on the order of 4.9 eV. The work function of antimony which makes up the n-side gate electrode 111 is on the order of 4.2 eV, according to experiments conducted by the inventor. In this way, using a metal having a larger work function and a metal having a smaller work function for the p-side gate electrode 110P and the n-side gate electrode 111, respectively, achieves low switching voltage.

Antimony which makes up the n-side gate electrode 111 is less likely to diffuse into other layers as well as absorb oxygen atoms and the like. Therefore, electrical characteristics may be increased, including low switching voltage, in view of diffusion and absorption.

It has been believed that using antimony as a material for electrodes is very difficult. This is because antimony may sublime at a low temperature on the order of 400° C., and therefore, it is not compatible with a thermal process for salicide. However, in the CMOS in FIG. 1, the platinum silicide (Sb) film 110N of approximately 50 nm thick is formed on the antimony precipitated layer 111 having thickness of 1 nm or less. Therefore, the platinum silicide (Sb) film 110N serves as a protection layer to prevent the antimony precipitated layer 111 from subliming in the salicide thermal process.

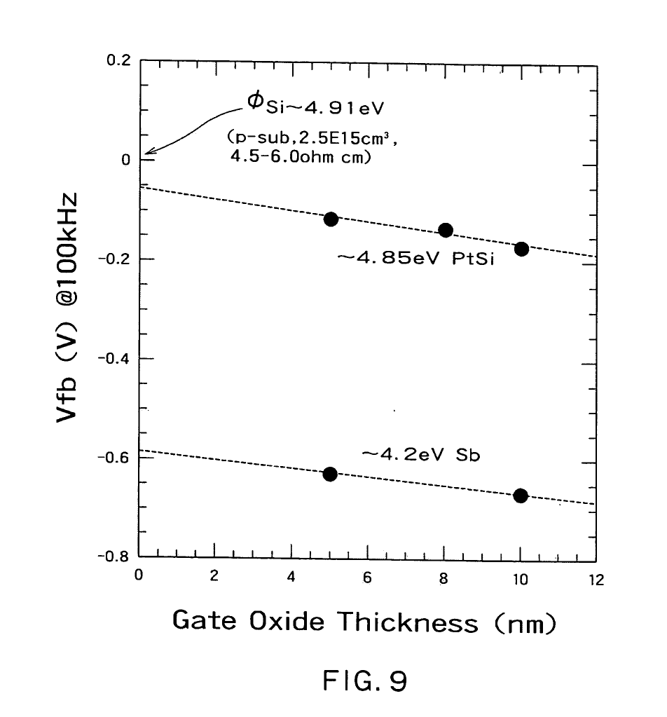

In view of a work function, using antimony as a material for the n-side metal gate electrode 111 opposes common senses in the art. This is because it has been known that a metal having the work function of less than 4.6 eV must be used as a material for the n-side metal gate electrode. Antimony has the work function on the order of 4.5 to 4.9 eV (for example, see “Applied Physics Data Book” (Maruzen Co., Ltd.), p. 495), and therefore, has not been considered to be a material suitable for the n-side metal gate electrode. However, according to experiments conducted by the inventor, good electrical characteristics have been obtained with an n-type MOSFET which uses antimony as the material for the n-side metal gate electrode 111 as shown in FIG. 1. As a result of detailed analysis on the n-side metal gate electrode conducted by the inventor, it has been found that thin antimony formed on the insulating film 102N has the work function of approximately 4.2 eV. This will be described below with reference to FIG. 9.

FIG. 9 is an experimental data by which the work function of thin antimony (Sb) formed on a gate oxide is determined. The abscissa axis and the ordinate axis show thickness (nm) of the gate insulating films and values of flatband voltages Vfb at 100 kHz, respectively. In these experiments, a flatband voltage is first measured using a gate oxide (gate insulating film) having thickness of 10 nm, and the measurement is plotted. Then, another flatband voltage is measured using a gate oxide having half the thickness of it. Then, these two points of value are connected to determine a point of intersection with the ordinate axis. The point of intersection may be compared to those of silicon and platinum silicide (PtSi), and the work function of antimony is determined to be approximately 4.2 eV.

In this way, the work function of thin antimony formed on the insulating film 102N has been found to be 4.2 eV according to experiments conducted by the inventor, although the work function of antimony has been 4.5 to 4.9 eV according to common senses in the art. This is because the inventor assumes that the work function data of antimony has been measured by irradiating photoelectrons onto a single body, mass of antimony, and the thin antimony formed on the insulating film 102N may have a different value of the work function than the mass of antimony.

In this way, it has been found that using antimony for the n-side metal gate electrode 111 may provide good electrical characteristics.

In the CMOS in FIG. 1 described above, although thickness of approximately 1 nm or less is used for the antimony precipitated layer 111, a thicker layer may be used. The antimony precipitated layer 111 is formed by ion-implanting antimony atoms into the n-side polysilicon film 103N and causing the antimony atoms to be precipitated by the snow plowing effect in silicide, as described above. Therefore, to provide a thick antimony precipitated layer 111, the amount of ion-implanted antimony atoms may be increased. For example, the ion implantation dose of antimony on the order of 1E16/cm² results in an average antimony concentration on the order of 2% in the polysilicon film 103N before forming silicide, and results in thickness of the antimony precipitated layer 111 on the order of 1 nm. The dose may be increased in order to provide an antimony precipitated layer thicker than 1 nm. However, in view of productivity and/or reliability, the antimony precipitated layer may preferably be 5 nm or less, and more preferably 1 nm or less.

Additionally, in the CMOS in FIG. 1, although the n-side gate electrode 111 in the n-type MOSFET is made up of antimony, indium may be used instead of antimony. Specifically, indium may be ion-implanted instead of antimony in the step of FIG. 3 as described above, so that the n-side gate electrode 111 may be an indium precipitated layer. The work function of indium is at least less than 4.6 eV, and it is approximately 4.1 eV according to experiments conducted by the inventor. The value of approximately 4.1 eV is approximately the same that of conventional gate electrode using polysilicon. In addition, using a metal, or indium, for the gate electrode prevents the gate from being depleted in contrast to such a gate electrode made of polysilicon. Therefore, lower threshold voltage and/or lower switching voltage may be achieved in comparison to the conventional CMOS transistors.

In the step of FIG. 3 as described above, antimony and indium may also be ion-implanted at the same time to produce an alloy of antimony and indium for the n-side gate electrode 111 in the n-type MOSFET. In this case, the work function can be varied depending on a ratio of antimony and indium.

Additionally, in the CMOS in FIG. 1, although platinum silicide is used for the p-side gate electrode 110P, palladium silicide may also be used for this. The palladium silicide has the work function on the order of 4.9 eV, or at least a value larger than 4.6 eV, as is the case with platinum silicide, and it is suitable to the p-side gate electrode.

Further, although the CMOS in FIG. 1 is fabricated without ion implantation into the polysilicon film 103 in the n-type MOSFET region in the step of FIG. 3, tellurium or selenium may be ion-implanted to fabricate the device as required. In this case, tellurium or selenium is driven near an interface between the p-side gate insulating film 102P (FIG. 1) and p-side gate electrode 110P, increasing the concentration of tellurium or selenium near the interface. The concentration on the order of a few tens of percent may enable the work function of the p-side gate electrode 110P. In this case, tellurium or selenium is not a metal, and therefore, a complete precipitated layer is not necessarily required to be formed in order to vary the work function.

Additionally, in the CMOS in FIG. 1, the amount of impurities contained in the PtSi film may be varied to specify any value of the work function for the gate electrode within a certain range. Therefore, multiple MOSFETs with different thresholds may be formed on the same substrate. For power elements and the like, the thresholds may be increased in a purposeful way as required.

### Second Embodiment

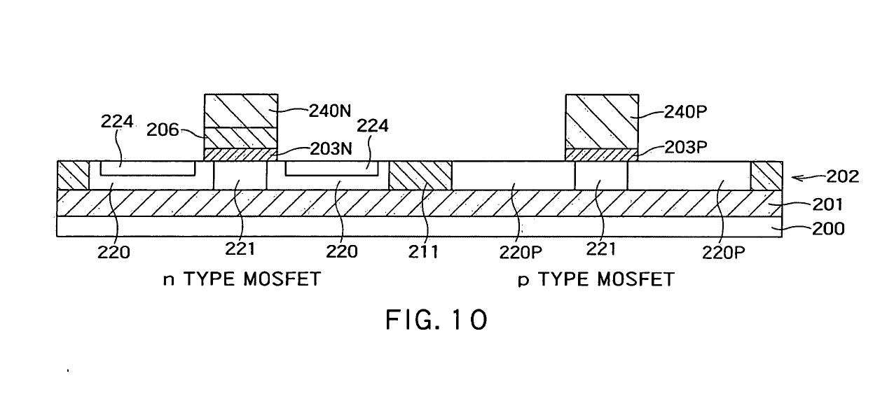

One difference in a CMOS of a second embodiment from that of the first embodiment (FIG. 1) is that, as can be seen in FIG. 10 for example, it uses an SOI (Silicon On Insulator) substrate which has an Si substrate 200, an insulating film 201 formed on the Si substrate, and an SOI layer 202 of approximately 10 nm thick formed on the insulating film 201. It also uses antimony precipitated layers for n-side schottky source and drain electrodes 220.

Specifically, FIG. 10 is a sectional view of CMOS transistors of the second embodiment according to the present invention. An isolation region 211 is formed on the SOI layer 202 in the SOI substrate which has the Si substrate 200, the insulating film 201 formed on the Si substrate, and the SOI layer 202 of approximately 10 nm thick formed on the insulating film 201. An n-type MOSFET is formed on the left side of the isolation region 211, and p-type MOSFET on the right side. In the p-type MOSFET on the right side of the drawing, source and drain electrodes 212 made of PtSi, and a channel region 221 are formed in portions of the SOI layer 202. A p-side gate insulating film 203P made of silicon oxynitride of approximately 1 nm thick is formed on the SOI layer 202. A platinum silicide (PtSi) film 204P of approximately 20 nm thick is formed on the p-side gate insulating film 203P. The platinum silicide film 204P is used for a p-side gate electrode. Similarly, in the n-type MOSFET on the left side of the drawing, schottky source and drain electrodes 220 made of an antimony precipitated layer, source and drain wiring layers 224 made of PtSi (Sb), and a channel region 221 are formed in portions of the SOI layer 202. A n-side gate insulating film 203N made of silicon oxynitride of approximately 1 nm thick is formed on the SOI layer 202. A thin (5 nm or less), antimony precipitated layer 206 is formed on the n-side gate insulating film 203N. The antimony precipitated layer 206 is used for an n-side gate electrode. A platinum silicide (PtSi) film 240N is formed on the n-side gate electrode 206, and the platinum silicide film 240N is used for an n-side gate wiring layer.

A method for manufacturing the CMOS in FIG. 10 will now be described.

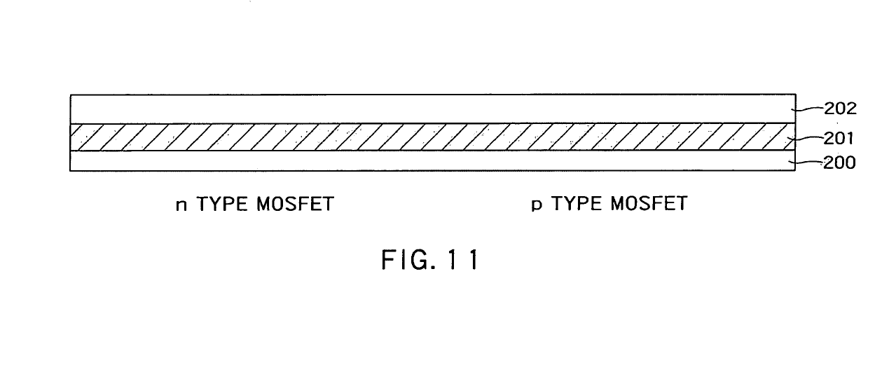

(1) As shown in FIG. 11, the SOI (Silicon On Insulator) substrate 202 which has the Si substrate 200, the insulating film 201, and the SOI layer 202 of approximately 10 nm thick is provided. In the drawing, a region for forming n-type MOSFETs is to the left, and a region for forming p-type MOSFETs is to the right.

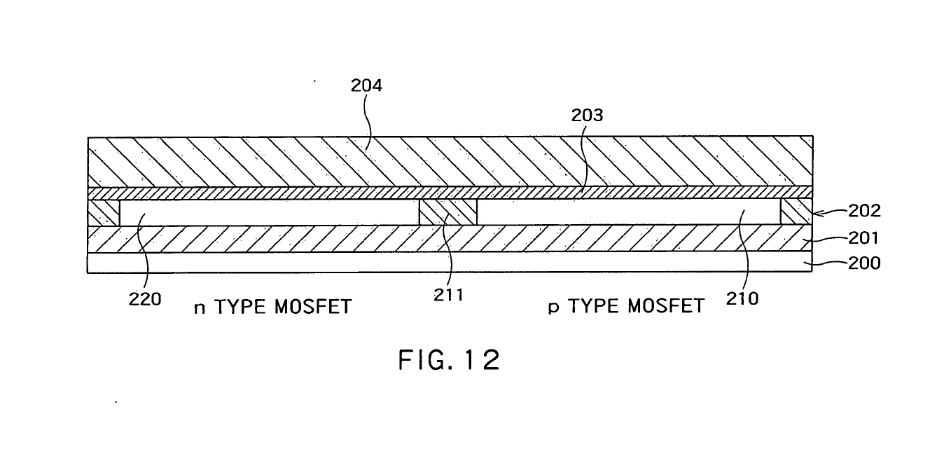

(2) Then, as shown in FIG. 12, the isolation region 211 is formed using a technique such as STI. Then, the gate insulating film 203 made of silicon oxynitride on the order of 1 nm is deposited and a polysilicon film 204 on the order of 20 nm is deposited.

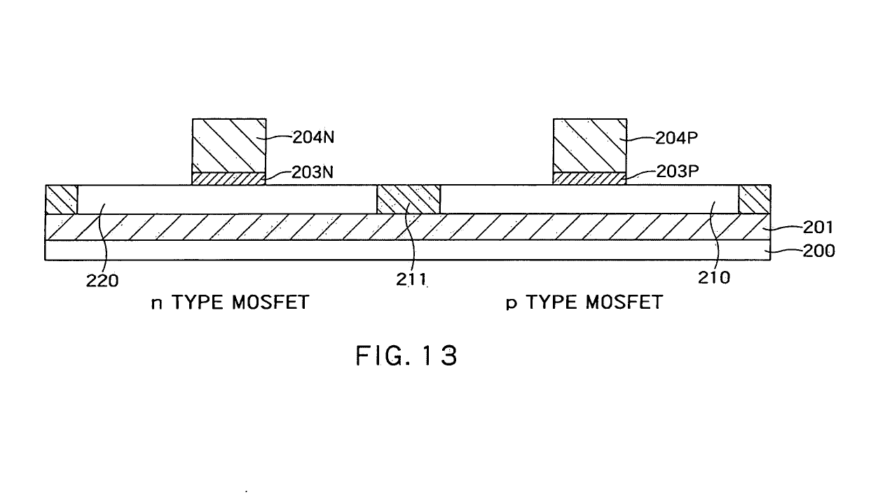

(3) Then, as shown in FIG. 13, lithography and etching techniques are used to shape the polysilicon film 204 into gates, and thus a polysilicon film 204N on the n-side and a polysilicon film 204P on the p-side are formed. Then, portions of the gate insulating film 203 (on the surfaces of source and drain regions) other than those in p-side and n-side gate electrode sections are wet-etched away to form the p-side gate insulating film 203P and n-side gate insulating film 203N.

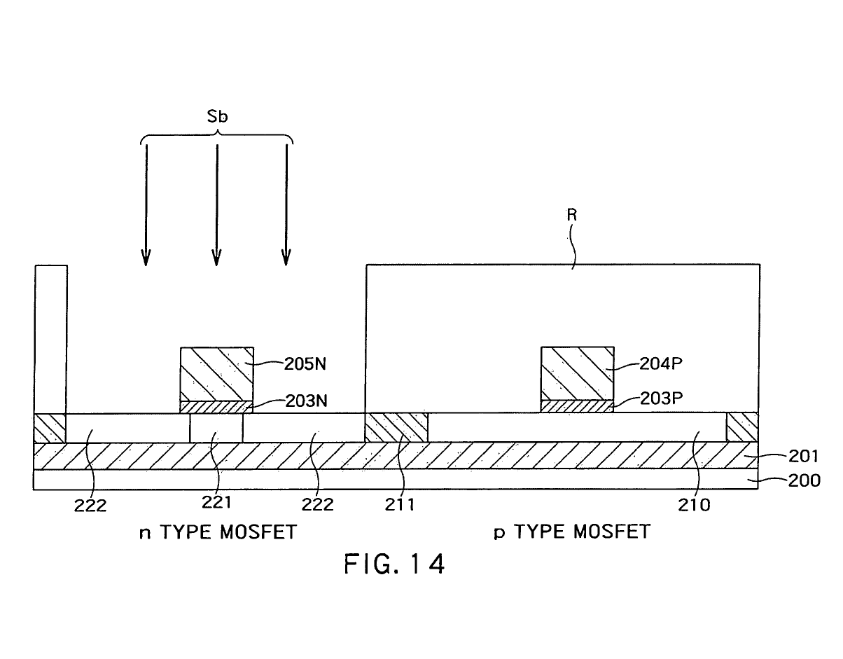

(4) Then, as shown in FIG. 14, lithography techniques are used to cover the p-type MOSFET region with photoresist R to ion-implant antimony into the n-type MOSFET region. Antimony is thus injected into the n-side polysilicon film 204N, creating a polysilicon (Sb) film 205N. Antimony is also injected into the n-side, creating source and drain regions 222. The ion implantation dose of antimony at this time is on the order of 2E16/cm².

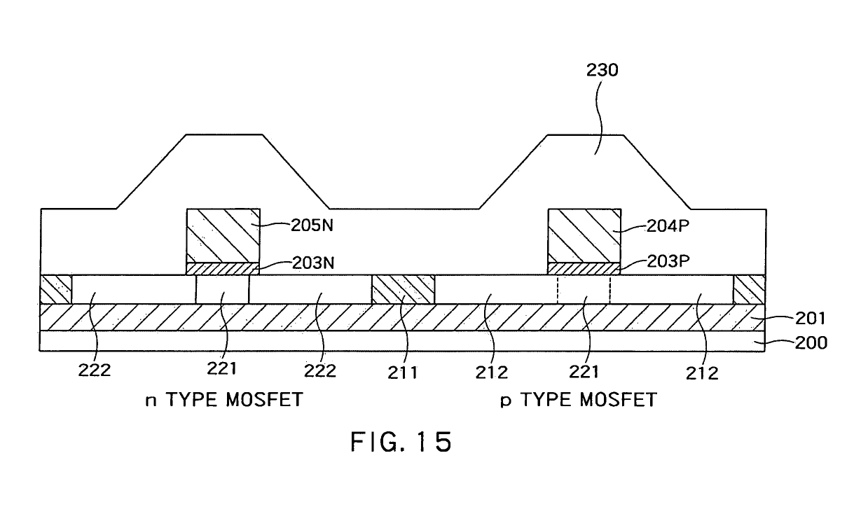

(5) Then, the photoresist R in FIG. 14 is removed. In p-type MOSFET, source and drain regions 212 and a channel region 221 are formed in a conventional way. At this point, thermal processes may be performed to diffuse antimony into n-side polysilicon (Sb) film 205N and/or n-side source and drain regions 22. Thereafter, as shown in FIG. 15, a Pt film 230 of approximately 20 nm thick is formed by sputtering.

(6) Then, salicide techniques are used to transform the n-side polysilicon (Sb) film 205N, the n-side source and drain regions 222, the p-side polysilicon film 204P, and the p-side source and drain regions 212 in FIG. 15 into PtSi. At this time, the thermal processes are adjusted to transform all the regions 205N, 222, 204P and 212 into PtSi. The thickness of the Pt film 230 is also adjusted as required. In this embodiment, the source and drain regions 222 and 212 have thickness of approximately 10 nm, while the polysilicon films 205N and 204P have thickness of approximately 20 nm. Therefore, because the polysilicon films 205N and 204P are thicker, a thermal process for salicide and/or thickness of Pt film 230 may be adjusted to transform all the polysilicon films 205N and 204P into PtSi. Specifically, temperature of a thermal process is 400° C. and thickness of Pt film is 20 nm. This thermal process induces a salicide reaction. During the salicide reaction, antimony atoms contained in the n-side polysilicon (Sb) film 205N may be ejected (snow plowing effect), and thus ejected antimony precipitates as the antimony precipitated layer (n-side gate electrode) 206 having thickness of 5 nm or less while the n-side PtSi (Sb) layer 240 (FIG. 10) is formed. Additionally, in the n-side source and drain regions 222 (FIG. 15), the phenomenon, that antimony atoms contained in these regions 222 may be driven to right and left and downward in the drawing, is occurred (snow plowing effect). As a result, the source and drain electrodes 220 made of antimony precipitated layers are formed while the n-side PtSi (Sb) film 224 is formed. Thereafter, unreacted portions of the Pt film 230 are removed by such as royal water, and thus the CMOS in FIG. 10 is formed.

The CMOS in FIG. 10 formed by a method described above suffers less degradation of reliability and/or mass productivity over conventional CMOS transistors which use polysilicon for their gate electrodes, as is the case with the first embodiment.

Additionally, the CMOS in FIG. 10 has dual metal gate electrodes, and the n-side gate electrode 206 is the antimony precipitated layer and the p-side gate electrode 204P is the PtSi film. This may achieve low switching voltage, as is the case with the first embodiment.

Furthermore, the CMOS in FIG. 10 has dual schottky source and drain electrodes in which the n-side source and drain electrodes 220 are the antimony precipitated layers and the p-side source and drain electrodes 212 are the PtSi films. This may further improve electrical characteristics.

Additionally, in the CMOS in FIG. 10, the amount of Sb to be contained in the n-side polysilicon (Sb) film 205N and n-side source and drain regions 222 may be varied during fabrication (FIG. 14) to specify any value of the work function for the gate electrode within a certain range. Therefore, multiple MOSFETs with different thresholds may be formed on the same substrate. For power elements and the like, the thresholds may be increased in a purposeful way as required. These features are especially useful in an SOI substrate as is the case with this embodiment. In operation, the SOI substrate operatively depletes silicon in the channel section 221 completely; that is, fully depleted operation. Full depletion provides an advantage such as reliable operation of a MOSFET because channels may be formed in lower vertical electric field. However, although an SOI substrate has such an advantage, it has a disadvantage that impurity concentration may not easily be varied in the channel section 221. This is because higher impurity concentration in the channel section hinders full depletion in the channel section 221. This means that, in the SOI substrate, thresholds cannot be varied by changing impurity concentration in the channel section 221. Therefore, in the SOI substrate, it is required to change the work function of the gate electrode in order to vary the thresholds. However, in conventional CMOS transistors which use polysilicon for their gate electrodes, the work functions are fixed at 4.1 eV in the n-side gate electrode and 5.2 eV in p-side gate electrode. Therefore, in these conventional CMOS transistors, it is difficult to form multiple MOSFETs with different thresholds on the same substrate and/or to increase the thresholds in a purposeful way as required. On the other hand, the CMOS of the embodiment enables the work function of the gate electrode to arbitrarily be varied as described above, and therefore, it is possible to form multiple MOSFETs with different thresholds on the same substrate and/or to increase the thresholds in a purposeful way as required.

In the CMOS in FIG. 10 described above, although SOI is illustratively used as an element operating in a fully depleted manner, the features of the embodiment remains the same in other cases unless an element operates in a fully depleted manner. For example, a double gate MOSFET having two gates may similarly operate in a fully depleted manner. The double gate MOSFET is a type of a MOSFET in which a channel made of semiconductor is formed between a pair of oppositely formed gate electrodes having same potential. In these cases, the work function of the gate electrode must be varied to change the thresholds.

In the first and second embodiments, a method which takes advantage of the snow plowing effect in antimony, indium, or both antimony and indium in the n-type MOSFET has been described. However, the present invention may also be used in a method which takes advantage of the snow plowing effect in selenium, tellurium, or both selenium and tellurium in the p-type MOSFET.

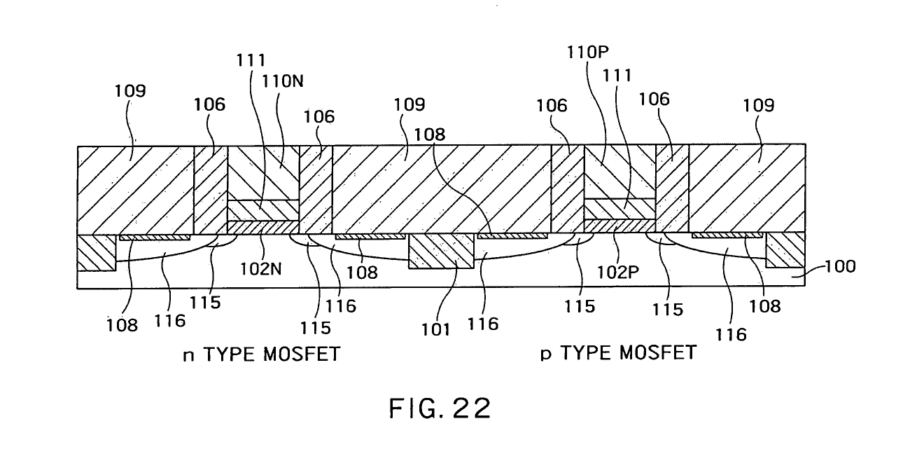

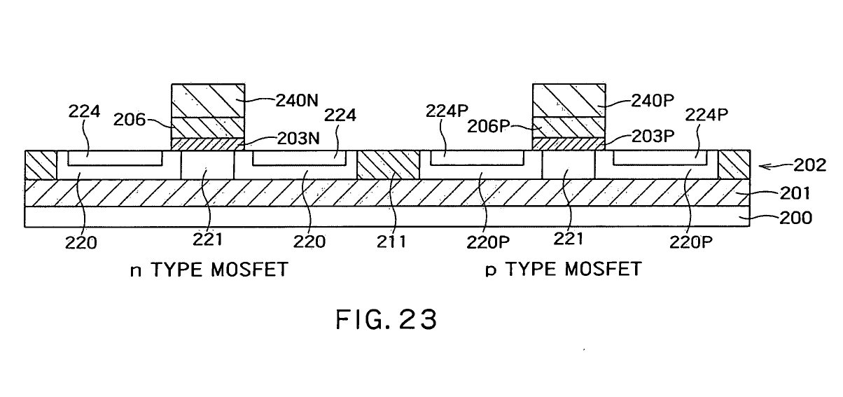

Furthermore, as variations of the first and second embodiments, a p-type MOSFET may be constructed to have high concentration layers 111P (FIG. 22), 206P, 220P (FIG. 23) containing either of selenium or tellurium, or both, by 1E21/cm³ or more, as shown in FIGS. 22 and 23. In FIG. 23, the layer 206P is the p-side gate electrode consisting of a precipitated layer of selenium or tellurium, and the layer 220P is the source and drain electrodes consisting of a precipitated layer of selenium or tellurium. Similarly, for example, the layer 240P is a platinum silicide film and the layer 224P is source and drain wiring layers consisting of a platinum silicide film.

According to embodiments of the present invention, a semiconductor device which uses metal gate electrodes and which is highly reliable and easy to fabricate in mass production, and a method for manufacturing the same, may be provided.

What is claimed is:

1. A semiconductor device having a plurality of MOSFETs formed on a semiconductor substrate, a gate electrode in at least one particular MOSFET of the MOSFETs comprising:
a first metal layer being the undermost layer; and
a silicide layer over the first metal layer.

2. The semiconductor device according to claim 1, wherein the silicide layer is platinum silicide layer or palladium silicide layer.

3. The semiconductor device according to claim 2, comprising at least one CMOS as the plurality of MOSFETs, wherein an n-type MOSFET in the CMOS is the particular MOSFET among the n-type MOSFET and a p-type MOSFET.

4. The semiconductor device according to claim 1, wherein the first metal layer comprises any one of indium, antimony, and an alloy containing the indium and antimony.

5. The semiconductor device according to claim 3, wherein a gate electrode in the p-type MOSFET in the CMOS comprises platinum silicide layer or palladium silicide layer, the platinum silicide layer or the palladium silicide layer is the same material for the suicide layer in the n-type MOSFET.

6. The semiconductor device according to claim 5, wherein the first metal layer comprises any one of indium, antimony, and an alloy containing the indium and antimony.

7. The semiconductor device according to claim 6, wherein, in each of the n-type MOSFET and p-type MOSFET in the CMOS, a surface of each source and drain is provided with a silicide.

8. The semiconductor device according to claim 1, wherein an SOI substrate is used for the semiconductor substrate.

9. The semiconductor device according to claim 5, further comprising an underlayer of high concentration containing at least one of selenium and tellurium under the platinum silicide layer or the palladium silicide layer of the gate electrode in the p-type MOSFET in the CMOS.

10. The semiconductor device according to claim 9, wherein an SOI substrate is used for the semiconductor substrate.

11. The semiconductor device according to claim 1, wherein thickness of the first metal layer is 5 nm or less.

12. A method for manufacturing a semiconductor device, comprising:
comprises polysilicon film on a gate insulating film comprises on a semiconductor substrate;
introducing a first metal into a portion of a region of the polysilicon film;
forming a pre-gate electrode from the polysilicon film, the polysilicon film having the first metal introduced; and
transforming the pre-gate electrode into a silicide in its entirety to form a suicide film and to form a metal layer by causing the first metal to be precipitated between the gate insulating film and the silicide film.

13. The method for manufacturing a semiconductor device according to claim 12, wherein
the first metal layer comprises one of indium, antimony, and an alloy containing the indium and antimony, and
the silicide film comprises any one of platinum silicide or palladium silicide.

14. A method for manufacturing a semiconductor device having a plurality of MOSFETs, a gate electrode in at least one particular MOSFET of the MOSFETs is formed by:
forming polysilicon film on a gate insulating film formed on a semiconductor substrate;
introducing a first metal into a portion of a region of the polysilicon film;
forming a pre-gate electrode from the polysilicon film, the polysilicon film having the first metal introduced; and
transforming the pre-gate electrode into a silicide in its entirety to form a silicide film and to form a metal layer by causing the first metal to be precipitated between the gate insulating film and the silicide film.

15. The method for manufacturing a semiconductor device according to claim 14, wherein
the first metal layer comprises one of indium, antimony, and an alloy containing the indium and antimony, and
the silicide film comprises any one of platinum silicide or palladium silicide.

16. The method for manufacturing a semiconductor device according to claim 14, wherein at least one CMOS is formed as the plurality of MOSFETs, and an n-type MOSFET among the n-type MOSFET and a p-type MOSFET constituting the CMOS is formed as the particular MOSFET.

17. The method for manufacturing a semiconductor device according to claim 16, wherein the gate electrode in the n-type MOSFET and a gate electrode in the p-type MOSFET are formed by:
forming platinum film or palladium film on the pre-gate electrode in the n-type MOSFET and on the pre-gate electrode in the p-type MOSFET, the pre-gate electrode in the p-type MOSFET being formed from the polysilicon film; and
performing a silicide process in the state.

18. The method for manufacturing a semiconductor device according to claim 14, wherein an SOI substrate is used for the semiconductor substrate.

19. The method for manufacturing a semiconductor device according to claim 17, wherein the gate electrode in the p-type MOSFET in the one CMOS are formed by:
introducing at least one of selenium and tellurium into the pre-gate electrode in advance; and
performing the silicide process on the pre-gate electrode to form a silicide film and to form a metal layer by causing at least one of the selenium and the tellurium to be precipitated between the gate insulating film and the silicide film.

20. The method for manufacturing a semiconductor device according to claim 19, wherein an SOI substrate is used for the semiconductor substrate.
